(19) United States
(12) Patent Application Publication
(10) Pub. No.: US 2017/0322487 A1
(43) Pub. Date: Nov. 9, 2017

(54) SLA RESINS AND METHODS OF MAKING AND USING THE SAME

(71) Applicant: ARCONIC INC., Pittsburgh, PA (US)

(72) Inventors: Cary Baur, Monroeville, PA (US); Albert Askin, Lower Burrell, PA (US); David Cook, Hart, MI (US); Jennifer Giocondi, Pittsburgh, PA (US); Jean Ann Skiles, Gibsonia, PA (US); Shawn Sullivan, Oakmont, PA (US); Rick Kniffel, Muskegon, MI (US); John T. Siemon, Cheswick, PA (US)

(21) Appl. No.: 15/590,696

(22) Filed: May 9, 2017

Related U.S. Application Data
(60) Provisional application No. 62/333,398, filed on May 9, 2016.

(51) Int. Cl. G03F 7/00; C08G 59/68; C08G 59/62; C08G 59/24; B33Y 70/00; C09D 163/00; B33Y 10/00

(52) U.S. Cl. CPC G03F 7/0037; C09D 163/00; C08G 59/687; B33Y 10/00; C08G 59/24; B33Y 70/00; C08G 59/62

(57) ABSTRACT

The present disclosure is directed towards resin compositions and methods of making and using the same, where the resulting resins (e.g. SLA resins) can be utilized in conjunction with additive manufacturing.

### CROSS-REFERENCE TO RELATED APPLICATIONS

This application is a non-provisional of and claims priority to U.S. Application Ser. No. 62/333,398, entitled “SLA Resins and Methods of Making and Using the Same” filed on May 9, 2016, which is incorporated by reference in its entirety.

### FIELD OF THE INVENTION

Generally, the present disclosure is directed towards Stereolithography (SLA) resins that include a macro dendritic component therein. More specifically, the present disclosure is directed towards SLA resins which utilize hyperbranched polyesters to create AM parts.

### BACKGROUND

SLA printing (also broadly referred to as three-dimensional printing or additive manufacturing) relies upon UV curable polymers as feedstocks for additively forming (curing) objects into discrete shapes from resins having desired properties.

### SUMMARY OF THE DISCLOSURE

Broadly, the present disclosure relates to stereolithographic resin (SLA resin) compositions and/or products regarding the same. More specifically, the present disclosure relates to SLA resins as additive manufacturing feedstocks, and SLA products configured from additively manufactured SLA resin compositions.

As used herein, “SLA resin” refers to a stereolithographic resin. For example, SLA resins can be utilized as a build material and/or feed stock used in conjunction with vat polymerization and/or an SLA.

In some embodiments, the SLA resin is a UV curable polymer system. In some embodiments, the SLA resin is employable in additive manufacturing. In some embodiments, the SLA resin is directed, deposited, positioned, spread, extruded, and/or sprayed into place prior to curing. In some embodiments, the SLA resin is directed, deposited, positioned, spread, extruded, sprayed, dropped (deposited via droplets), extruded, cast, molded, and/or combinations thereof (e.g. in order to form a layer of SLA resin).

In some embodiments, the layer of SLA resin is cured (e.g. photocured UV cured) in order to form the SLA preform. In some embodiments, successive layers of SLA resin are repeatedly/iteratively deposited and cured (e.g. UV cured) in order to form an additively manufactured SLA AM preform. In some embodiments, once the SLA AM preform is built, it is post cured to create an AM part or product (e.g. configured from cured, SLA resin material).

In one embodiment, an SLA resin includes the following components: a hyperbranched polyester and a photo initiator, and optionally, an epoxy component, a reactive diluent, a stabilizer, and a pigment.

In one embodiment, an SLA resin includes the following components: a hyperbranched polyester, an epoxy component, and a photo initiator, and optionally, a reactive diluent, a stabilizer, a pigment and/or combinations thereof.

In one embodiment, an SLA resin includes the following components: a hyperbranched polyester, epoxy component, a reactive diluent, and a photo initiator, and optionally, a stabilizer, a pigment, and/or combinations thereof.

In one embodiment, an SLA resin includes the following components: a hyperbranched polyester, epoxy component, a reactive diluent, and a photo initiator, a stabilizer, and optionally, a pigment.

In one embodiment, an SLA resin includes the following components: a hyperbranched polyester, epoxy component, a reactive diluent, and a photo initiator, a pigment, and optionally, a stabilizer.

In one embodiment, an SLA resin includes the following components: a hyperbranched polyester, epoxy component, a reactive diluent, and a photo initiator, a pigment, and a stabilizer.

In some embodiments, a dendritic macromolecule is utilized in the SLA resin in place of an acrylate component. In some embodiments, the dendritic macromolecule comprises a hyperbranched polyester material. Some non-limiting examples of a hyperbranched polyester including Bottom H2004.

As used herein, “epoxy” (also called epoxy resins) means: any of a class of resins derived by polymerization from epoxides. As a non-limiting example, epoxies include cycloaliphatic epoxies.

As used herein, “diluent” means: a component added to another component in order to reduce viscosity and/or thin the material.

As used herein, “reactive diluent” means: a component in the SLA resin which acts to reduce viscosity and/or provide/contribute to the polymerization reaction/cross-linking of the resin material. Some non-limiting examples of reactive diluents are compounds having four membered rings (e.g. oxetane).

As used herein, “photo initiator” means: a substance that after being illuminated by light, is configured to initiate or enhance a chemical reaction (although the substance itself may not undergo a reaction). In some embodiments, the photo initiator catalyzes the reaction/cross-linking of the SLA resin components, when activated by an energy source (e.g. light or laser beam) during an AM process.

In one embodiment, the photo initiator is an antimony free photo initiator. In some embodiments, the antimony free photo initiator is configured to reduce, prevent, and/or eliminate residue after burning out of the STA resin.

Some non-limiting examples of photo initiators include onium salts. In some embodiments, the onium salts are configured as a solution (e.g. 60% salt content and 40% solvent). (As used herein, the referenced photo initiator amount generally refers to the total solution content that was added (i.e. and not the active photo initiator chemical salt portion of the solution).

Some non-limiting examples of onium salts include: iodium, sulfonium, ammonium, and phosphonium. Some non-limiting examples of non-nucleophile counterions for the onium salts may include: BF4-, PF6-, Br-, SbF6-, and combinations thereof.

In some embodiments, the photo initiator (e.g. photo initiator solution) is: a triaryisullonium hexafluorophosphate salt (bis and thiol salts), commercially available PF6 CPI6992 (Aceto Corp.). In some embodiments, the photo initiator is: a triarylsulfonium hexathorophosphate salt (e.g. bis salts).

As used herein, “stabilizer” means: a material configured to keep other material(s) stable (e.g. unreacted, uncured). In some embodiments, stabilizers are utilized in the SLA resin mixture, e.g. to prevent curing and/or side reactions/chemical interactions outside of the additive manufacturing environment.

As used herein, “pigment” means: an additive utilized for adding color or changing the color of a material. As used herein, pigments also include dyes and/or colorants.

As used herein, “additive manufacturing” means: a process of joining materials to make objects from 3D model data, usually layer upon layer, as opposed to subtractive manufacturing methodologies.

As used herein, “additive system(s)” means: machine(s) used for additive manufacturing. As some non-limiting examples, additive manufacturing machines operate under various process categories, which refers to a category of machines rather than a particular commercial vendor/variation of process methodology.

Some non-limiting process categories include: binder jetting, directed energy deposition; material extrusion; material jetting; powder bed fusion; sheet lamination; and vat photopolymerization.

As used herein, “vat photopolymerization” means: an additive manufacturing process in which liquid photopolymer in a vat is selectively cured by light-activated polymerization.

As used herein, “stereolithography” (SLA) means: a vat photopolymerization process used to produce parts from photopolymer materials in a liquid state using one or more lasers to selectively cure to a predetermined thickness and harden the material into shape layer upon layer.

As used herein, “stereolithography apparatus” (SLA) means: an SLA additive machine. As a nonlimiting example, SL additive machines are commercially available through various vendors, including 3D Systems Corporation, EnvisionTEC 3D, Formlabs, etc.

As used herein, “binder jetting” means: an additive manufacturing process in which a liquid bonding agent is selectively deposited to join powder materials.

As used herein, “directed energy deposition” means: an additive manufacturing process in which focused thermal energy is used to fuse materials by melting as they are being deposited. (In some embodiments, the focused thermal energy refers to the energy source (e.g. laser, electron beam, or plasma arc) that is focused to melt the materials being deposited.

As used herein, “material extrusion” means: an additive manufacturing process in which material is selectively dispensed through a nozzle or orifice.

As used herein, “powder bed fusion” means: an additive manufacturing process in which thermal energy selectively fuses regions of a powder bed.

As used herein, “sheet lamination” means: an additive manufacturing process in which sheets of material are bonded to form an object.

As used herein, “material extrusion” means: an additive manufacturing process in which material is selectively dispensed through a nozzle or orifice.

As used herein, “material jetting” means: an additive manufacturing process in which droplets of build material (e.g. photopolymer, wax, or combinations thereof) are selectively deposited.

In one aspect of the present disclosure a composition is provided, comprising: an epoxy component; a reactive diluent component; a macro dendritic component; and a photo initiator component; configured in an amount to catalyze the epoxy, the reactive diluent, and the macro dendritic component into a resin configured for additive manufacturing an AM component via vat polymerization.

In some embodiments, the composition includes: a stabilizer component configured to stabilize the composition and prevent polymerization outside of the vat polymerization process.

In some embodiments, the composition comprises a pigment component configured to stabilize the composition and/or prevent polymerization outside of the intended SLA polymerization process, as well as providing the desired coloring.

In some embodiments, the photo initiator comprises a UV curable photo initiator.

In some embodiments, the macro dendritic component comprises: a hyperbranched polyester component.

In some embodiments, the photo initiator component comprises an onium salt solution.

In some embodiments, the reactive diluent component comprises an oxetane component.

In another aspect of the present disclosure, a composition is provided, consisting essentially of: an epoxy component; a reactive diluent component including an oxetane; a macro dendritic component having a hyperbranched polyester; and a UV curable photo initiator component; configured in an amount to catalyze the epoxy, the reactive diluent, and the macro dendritic component into an SLA resin configured for additively manufacturing an AM component via stereolithography.

In some embodiments, the epoxy component comprises: a 3,4-epoxycyclohexylmethyl 3,4-epoxycyclohexanecarboxylate.

In another aspect of the present disclosure, a composition is provided comprising (e.g. consisting of—acrylate free composition): at least 60 wt. % to not greater than 85 wt. % of an epoxy component; at least 10 wt. % to not greater than 20 wt. % of a dendritic macromolecule component; and at least 0.05 wt. % to not greater than 15 wt. % of a photo initiator component.

In one aspect of the present disclosure, a composition is provided, consisting of: at least 50 wt. % to not greater than 85 wt. % of an epoxy component; at least 5 wt. % to not greater than 20 wt. % if of a dendritic macromolecule component comprising a hyperbranched polyester; not greater than 15 wt. % of a reactive diluent component, wherein at least some reactive diluent component is present; and at least 0.05 wt. % to not greater than 15 wt. % of a photo initiator component.

In some embodiments, the composition includes at least 0.5 wt. % to not greater than about 5 wt. % of a stabilizer component (e.g. based on the total weight of the resin).

In some embodiments, the stabilizer component ranges from 0.5 wt. %; to 2 wt. %, based on the total weight of the composition. In some embodiments, the stabilizer component ranges from 1.5 wt. %; to 2.5 wt. %, based on the total weight of the composition. In some embodiments, the stabilizer component ranges from 1 wt. %; to 3.5 wt. %, based on the total weight of the composition.

In some embodiments, the stabilizer component is: at least 0.5 wt. %; at least 1 wt. %; at least 1.5 wt. %; at least 2 wt. %; at least 2.5 wt. %; at least 3 wt. %, at least 3.5 wt. %; at least 4 wt. %; at least 4.5 wt. %; or at least 5 wt. % of the composition (based on the total weight of the composition).

In some embodiments, the stabilizer component is: not greater than 0.5 wt. %; not greater than 1 wt. %; not greater than 1.5 wt. %; not greater than 2 wt. %; not greater than 2.5 wt. %; not greater than 3 wt. %; not greater than 3.5 wt. %; not greater than 4 wt. %; not greater than 4.5 wt. %; or not greater than 5 wt. % of the composition (based on the total weight of the composition).

In some embodiments, the composition includes not greater than about 5 wt. % of a pigment component, wherein at least some pigment component is present (e.g. based on the total weight of the resin).

In some embodiments, the pigment component ranges from 0.5 wt. %; to 2 wt. %, based on the total weight of the composition. In some embodiments, the pigment component ranges from 1.5 wt. %; to 2.5 wt. %, based on the total weight of the composition. In some embodiments, the pigment component ranges from 1 wt. %; to 3.5 wt. %, based on the total weight of the composition.

In some embodiments, the pigment component is: at least some; at least 0.3 wt. %; 0.5 wt. %; at least 1 wt. %; at least 1.5 wt. %; at least 2 wt. %; at least 2.5 wt. %; at least 3 wt. %; at least 3.5 wt. %; at least 4 wt. %; at least 4.5 wt. %; or at least 5 wt. % of the composition (based on the total weight of the composition).

In some embodiments, the pigment component is; not greater than 0.5 wt. %; not greater than 1 wt. %; not greater than 1.5 wt. %; not greater than 2 wt. %; not greater than 2.5 wt. %; not greater than 3 wt. %; not greater than 3.5 wt. %; not greater than 4 wt. %; not greater than 4.5 wt. %; not greater than 5 wt. % of the composition; or not greater than 0.3 wt. % (based on the total weight of the composition),

In some embodiments, the epoxy component comprises: Uvacure 1500.

In some embodiments, the photo initiator component comprises an onium salt solution.

In some embodiments, the reactive diluent component comprises a compound having a four-membered ring.

In some embodiments, the reactive diluent component comprises an oxetane component.

In another aspect of the present disclosure, a method is provided, comprising: mixing a plurality of components consisting of: an epoxy component, a reactive diluent component, a hyperbranched polyester component, a stabilizer component, a pigment component, and a UV curable photo initiator component to form an SLA resin in a mixture; directing the SLA resin. onto a substrate to form a layer of SLA resin; energizing the SLA resin to cure the SLA. resin in selective positions along the layer of SLA resin to form a build pattern in the layer of SLA resin; repeatedly, directing and energizing the SLA resin to additively manufacture an AM preform; and curing the AM preform to create an AM part.

In another aspect of the present disclosure, a method is provided, comprising: mixing a plurality of components consisting of: an epoxy component, a hyperbranched polyester component, and a UV curable photo initiator component to form an SLA resin in a mixture: directing the SLA resin onto a substrate to form a layer of SLA resin; energizing the SLA resin to cure the SLA resin in selective positions along the layer of SLA resin to form a build pattern in the layer of SLA resin; repeatedly, directing and energizing the SLA resin to additively manufacture an AM preform; and curing the AM preform to create an AM part.

In another aspect of the present disclosure, a method is provided, comprising: mixing a plurality of components consisting of: an epoxy component, a reactive diluent component, a hyperbranched polyester component, and a UV curable photo initiator component to form an SLA resin in a mixture; directing the SLA resin onto a substrate to form a layer of SLA resin; energizing the SLA resin to cure the SLA resin in selective positions along the layer of SLA resin to form a build pattern in the layer of SLA resin; repeatedly, directing and energizing the SLA resin to additively manufacture an AM preform; and curing the AM preform to create an AM part.

In some embodiments, the energy source comprises an energy beam of the additive manufacturing machine.

In some embodiments, the directing step further utilizing an additive manufacturing machine (e.g. directing via an AM machine).

In some embodiments, the method includes, before the curing step, draining an uncured SLA resin material from the AM preform.

In some embodiments, the method includes, after the mixing step: degassing the mixture to remove entrapped gas bubbles from the SLA resin.

In another aspect of the present disclosure, a method is provided, comprising: additively manufacturing a plurality of AM parts, including a first AM part and a second AM part; applying an SLA resin to a portion of the first AM part; adhering the first AM part to a portion of the second AM part; curing the SLA resin positioned between the first AM part and second AM part to create an AM part assembly.

In some embodiments, the depositing, positioning, spreading, extruding, spraying, rolling, dipping, wiping, casting, and/or combinations thereof, to form a layer of SLA resin on a surface (e.g. substrate or previous AM build surface or layer).

In another aspect of the present disclosure, a method is provided comprising: additively manufacturing a plurality of AM green form parts from an SLA resin via vat polymerization, the SLA resin comprising: an epoxy component, a reactive diluent component, a hyperbranched polyester component, and a UV curable photo initiator component, the plurality of AM green form parts including at least a first AM green form part and a second AM green form part; applying an SLA resin to a portion of the first AM green form; curing the first AM green form, second AM green form and SLA resin positioned between the first AM green form and second AM green form to adhere the first AM green form part to the second AM green form part, thereby providing an AM green form assembly; and providing an AM part configured from the assembly of the AM green form parts and SLA resin.

In some embodiments, the vat polymerization process further comprises stereolithography.

In some embodiments, the AM part comprises a polymeric preform for investment casting.

In some embodiments, the AM part comprises a structural component.

In some embodiments, the AM part comprises a functional component.

In some embodiments, the SLA resin includes an epoxy, a reactive diluent, and a photo initiator (catalyst) with no acrylate component. In one or more embodiments, herein, the SLA resin comprises an acrylate-free resin.

In some embodiments, the SLA resin comprises an epoxy of: 3,4-epoxycyclohexylmethyl 3,4-epoxycyclohexanecarboxylate.

In some embodiments, the SLA resin comprises a macro dendritic molecule, i.e. a hyperbranched polyester material instead of/in place acrylate material.

In one embodiment, a UV curable polymer system (e.g. composition) is provided, comprising: a hyperbranched polyester; and a photo initiator.

In one embodiment, a composition is provided, including: a hyperbranched polyester; and a photo initiator, wherein the hyperbranched polyester is configured to be used as a UV curable feed material for an additive manufacturing machine. In one embodiment, an SLA resin is provided, the SLA resin comprising: a dendritic macromolecule therein.

In some embodiments, the dendritic macromolecule comprises a polyester. In some embodiments, the dendritic macromolecule comprises a hyperbranched polyester.

In some embodiments, a composition is provided, comprising: an epoxy (e.g. configured to be UV curable); a dendritic macromolecule (e.g. hyperbranched polyester), and a photo initiator (i.e. in a sufficient quantity to cure the composition when activated with a light source/UV source).

In one embodiment, a composition is provided comprising: an epoxy (e.g. configured to be UV curable) at a range of 60-85 wt. %; a dendritic macromolecule comprising a hyperbranched polyester at a range of 10-20 wt. %; and a photo initiator at a range of 0.05-15 wt. % (e.g. configured to cure in combination with a UV light source).

In some embodiments, a composition is provided, including: an epoxy (e.g. configured to be UV curable); a dendritic macromolecule (e.g. hyperbranched polyester), a photo initiator (in a sufficient quantity to cure the composition) (e.g. configured to cure in combination with a UV light source); and a reactive diluent (e.g. four membered ring, oxetane).

In some embodiments, a composition is provided, comprising an epoxy (e.g. configured to be UV curable) at about 75 wt. %; a dendritic macromolecule (e.g. hyperbranched polyester) at about 9 wt. %; a photo initiator solution at about 1.8 wt. % (in a sufficient quantity to cure the composition) (e.g. when configured/activated to cure in combination with a UV light source); and a reactive diluent at about 15 wt. %; (e.g. four membered ring, oxetane).

In some embodiments, a composition is provided, comprising: a UV curable epoxy comprising Uvacure 1500 at about 75 wt. %; a hyperbranched polyester comprising Boltorn H2004 at about 9 wt. %; a photo initiator solution comprising PF6 CP16992 at about 1.8 wt. %; and a reactive diluent comprising a four-membered ring (e.g. oxetane) at about 15 wt. % (e.g., Trimethylolpropane Oxetane, commercially available from Perstorp).

In some embodiments, an SLA AM preform is provided, consisting of: a hyperbranched polyester, an epoxy, a photoinitator; and optionally, a reactive diluent.

In some embodiments, the SLA resin comprises an acrylate free composition.

In some embodiments, the acrylate-free composition is configured to: reduce, prevent, and/or eliminate shrinkage of SLA part.

In some embodiments, the acrylate-free composition is configured to: reduce, prevent, and/or eliminate sensitivity to oxygen inhibition of acrylate curing mechanism. In some embodiments, the acrylate-free composition is configured to: reduce, prevent, and/or eliminate the addition of free radical photo initiator curing agent (i.e. needed if curing an acrylate-containing composition). In some embodiments, the acrylate-free composition is configured to be water resistant.

In some embodiments, the SLA resin is configured with flowability (e.g. low viscosity) as compared to commercially available SLA resins.

In one embodiment, a four-component SLA resin composition is provided, including: an epoxy, a dendritic polyester (e.g. hyperbranched polyester), an oxetane component (e.g. oxetane); and photo initiator (e.g. antimony free photo initiator).

In one embodiment, a three-component SLA resin composition is provided, including: an epoxy, a dendritic polyester (e.g. hyperbranched polyester), and photo initiator (e.g. antimony free photo initiator).

In some embodiments, the SLA resin composition is configured to be compatible with laser or projector based SLA equipment for 3D printing.

In some embodiments, the SLA resin composition is compatible with 2D printing equipment and photolithography.

In some embodiments, the SLA resin is configured for bulk curing.

In some embodiments, the components in the SLA resin composition are in accordance with the following range: 85 wt. % to greater than 0 wt % epoxy, (i.e. where at least some epoxy is present); 50 wt. %-0 wt. % oxetane type material (e.g. trimethylolopropane oxetane); 15 wt. %-1 wt. % polyester (e.g. dendritic or hyper branched polyester to include 6 to 1 branch); and 15 wt %-0.05 wt. % photo initiator (e.g. onium salt photo initiator),

In one embodiment, an SLA resin configured as an additive feedstock material includes: a range of 60-75 wt. % epoxy; 10-15 wt. % oxetane; 5-10 wt. % polyester (e.g. dendritic or hyperbranched polyester); and 8-10 wt. % photo initiator (e.g. containing an onium salt solution).

In some embodiments, the SLA resin composition includes an epoxy component at an amount of: not greater than 85 wt. %; not greater than 80 wt. %; not greater than 75 wt. %; not greater than 70 wt. %; not greater than 65 wt. %; not greater than 60 wt. %; not greater than 55 wt. %; not greater than 50 wt. %; not greater than 45 wt. %; not greater than 40 wt. %; not greater than 35 wt. %; not greater than 30 wt. %; not greater than 25 wt.; not greater than 20 wt. %; not greater than 15 wt. %; not greater than 10 wt. %; not greater than 5 wt. %; and not greater than 1 wt. % of the SLA resin.

In some embodiments, the SLA resin composition includes an epoxy component at an amount of: at least 85 wt. %; at least 80 wt. %; at least 75 wt. %; at least 70 wt. %; at least 65 wt. %: at least 60 wt. %, at least 55 wt. %; at least 50 wt. %; at least 45 wt. %; at least 40 wt. %; at least 35 wt. %; at least 30 wt. %; at least 25 wt.; at least 20 wt. %; at least 15 wt. %; at least 10 wt. %; at least 5 wt. %; and at least 1 wt. % of the SLA resin.

In some embodiments, the SLA resin includes epoxy in the following range: at least 5 to not greater than 85 wt. %; at least 20 to not greater than 75 wt. %; or at least 35 to not greater than 75 wt. %.

In some embodiments, the SLA resin includes an oxetane-type material/component at a content of: not greater than 50 wt. %; not greater than 45 wt. %; not greater than 40 wt. %; not greater than 35 wt. %; not greater than 30 wt. %; not greater than 25 wt. %; not greater than 20 wt. %; not greater than 15 wt. %; not greater than 10 wt. %; not greater than 5 wt. %; and not greater than 1 wt. %.

In some embodiments, the SLA resin includes an oxetane-type material/component at a content of: at least 50 wt. %; at least 45 wt. %; at least 40 wt. %; at least 35 wt. %; at least 30 wt. %; at least 25 wt. %; at least 20 wt. %; at least 15 wt. %; at least 10 wt. %; at least 5 wt. %; and at least 1 wt. %.

In some embodiments, the SLA resin includes an oxetane component present in the range of: 50 wt. % to 5 wt. % oxetane component; 40 wt. % to 10 wt. % oxetane component; 35 wt. % to 15 wt. % oxetane component.

In some embodiments, the SLA resin includes a polyester (e.g. hyperbranched polyester) in an amount of: not greater than 15 wt. %; not greater than 10 wt. %; not greater than 5 wt. %; and not greater than 1 wt. %.

In some embodiments, the SLA resin includes a polyester (e.g. hyperbranched polyester) in an amount of: at least 15 wt. %; at least 10 wt. %; at least 5 wt. %; and at least 1 wt. %.

In some embodiments, the SLA resin includes a polyester at an amount of: between 1.5 wt. %-1 wt. % polyester; between 10 and 5 wt. % polyester; and between 7 and 3 wt. % polyester.

In some embodiments, the SLA resin includes a photo initiator in an amount of: not greater than 15 wt. %; not greater than 10 wt. %; not greater than 5 wt. %; not greater than 1 wt. % photo initiator. In some embodiments, the SLA resin includes a photo initiator in an amount of: not greater than 5 wt. %; not greater than 3 wt. %; and not greater than 1 wt. %. In some embodiments, the SLA resin includes a photo initiator at a content of: not greater than 1 wt. %; not greater than 0.07 wt. %; or not greater than 0.05 wt. %.

In some embodiments, the SLA resin includes a photo initiator in an amount of: at least 15 wt. %; at least 10 wt. %; at least 5 wt. %; at least 1 wt. % photo initiator. In some embodiments, the SLA resin includes a photo initiator in an amount of: at least 5 wt. %; at least 3 wt. %; and at least 1 wt. %. In some embodiments, the SLA resin includes a photo initiator at a content of: at least 1 wt. %; at least 0.07 wt. %; or at least 0.05 wt. %.

In some embodiments, the RA resin includes a photo initiator in an amount of: 15 wt. %-0.05 wt. % photo initiator; 10 wt. % to 1.5 wt. %; and 8 wt. % to 3 wt. %.

Without being bound by a particular mechanism or theory, it is believed that when the SLA composition is in the presence of UV light and photo initiator, the epoxy rings and the oxetane rings open and can cross link with the dendritic polyester. With this configuration of components in the SLA resin, it is believed that the dendritic polyester adds flexibility to the crosslinked material through the addition of a flexible backbone, lower crosslink density, and potential plasticization. Also, without being bound by a particular mechanism or theory, it is believed that with the four-component system (e.g. including oxetane rings) the SLA resin is configured with a shorter cure speed (e.g. half the time) as compared to the three-component system (in the presence of the photo initiator and UV source).

Without being bound by any particular mechanism or theory, it is believed that the acrylate-free SLA resin is configured (e.g. via the reactive diluent and hyperbranched polyester) to provide an AM product with sufficient green strength, low ash content, and sufficient water resistance properties for application in an investment casting process.

In some embodiments, an analytical technique like FTIR is utilized to confirm the reaction of hyperbranched polyester and/or reactive diluent in the SLA composition and/or SLA AM part.

In some embodiments, an analytical technique to determine the reaction of hyperbranched polyester and/or reactive diluent in the SLA composition and/or SLA AM part is obtained by the Tg and/or TM values.

In some embodiments, the AM machine (e.g. 3D Systems SLA machine) was configured such that EC (critical exposure) varied from 7 to 13. In some embodiments, the AM machine was configured such that DP (depth of penetration) varied front 4-8.74. In some embodiments, the AM machine was configured with EC 9.98 and DP5.74. In some embodiments, the AM machine was configured with EC 9.98 and DP 4. In some embodiments, the AM machine was configured with EC 9.98 and DP 7. In some embodiments, the AM machine was configured with EC 1.3 and DP 5.74. In some embodiments, the AM machine was configured with EC7 and DP 5.74.

In one embodiment, the SLA resin comprises an additively manufactured investment pattern (e.g. airfoil, blade, or vein) for an investment casting process.

In one embodiment, the SLA resin comprises an additively manufactured pattern for a large structural investment casting process (e.g. frame for a jet engine).

In one embodiment, the SLA resin is configured into an additively manufactured part that is a prototype.

In one embodiment, the SLA resin comprises an additively manufactured part that is a functional part. In one embodiment, the SLA resin comprises an additively manufactured part that is a structural part.

In one embodiment, the SLA resin comprises an additively manufactured part that is a pattern.

In one embodiment, the SLA resin comprises an additively manufactured part that is a mold (e.g. for manufacturing other components/products).

In one or more of the aforementioned embodiments, the SLA resins are configured to be: lower viscosity photocurable mixtures, as compared to traditional SLA resins; and/or thermosetting as a post curing mechanism.

Various ones of the inventive aspects noted hereinabove may be combined to yield SLA resins, AM forms and/or parts composed/constructed of SLA resins, and/or parts configured from multiple AM forms that are attached, coated with a ceramic material, and burned off to yield a product formed from the AM parts (e.g. an investment casting).

These and other aspects, advantages, and novel features of the invention are set forth in part in the description that follows and will become apparent to those skilled in the art upon examination of the following description and figures, or may be learned by practicing the disclosed embodiments.

### BRIEF DESCRIPTION OF THE DRAWINGS

FIG. 1 is a graph depicting the experimental results of completing a thermogravimetric analysis of the SLA resin in accordance with one or more embodiments of the present disclosure, illustrating the comparative response of the SLA resin to a commercially available SLA resin.

FIG. 2 depicts a top plan view of two embodiments of AM parts constructed from a formulation of SLA resin in accordance with one or more embodiments of the present disclosure, where the part on the left (overcure 14) was cured after being additively manufactured with a lower overcure than the part on the right (overcure 32). It is observed that the lower overcure (faster laser speed) resulted in a lighter colored part than the part with the higher overcure (slower laser speed), which appears very dark in relation to the image on the left. (Overcure generally refers to the variable on the additive machine that changes the laser speed (length of time that a build portion undergoes polymerization), with an overcure rate of 14 being a lower setting of overcure faster laser speed) than an overcure rate of 32 (e.g. slower laser speed).)

FIG. 3 is a close-up cut away partial side view of an AM part build in accordance with one or more embodiments of the present disclosure, depicting a border wall (e.g. external wall) and an internal wall/cross-hatched wall (e.g. a plurality depicted, configured such that the AM part has an internal latticed structure in a honeycomb configuration). As depicted, one or more embodiments disclosed herein enable the AM machine to build AM parts with sufficient surface quality, build strength, wall thicknesses, fine features, and/or surface roughness to be utilized in applications including investment castings, molds, and the like, to name a few, in accordance with the present disclosure.

FIG. 4 depicts a graphical analysis of hardness(H) experimental data obtained from completing a nano-indentation analysis on an embodiment of man SLA resin in accordance with the present disclosure, as compared to a commercially available resin additively manufactured into an AM part with two different AM energy source parameters (EC/DP values). It is readily observable from FIG. 4 that the SLA resin of the present disclosure has a much higher hardness as compared to the commercially available SLA resin (at either AM laser build parameter).

FIG. 5 depicts a graphical analysis of Reduced Modulus (Er) experimental data obtained from completing a nano-indentation analysis on an embodiment of an SLA resin in accordance with the present disclosure, as compared to a commercially available resin additively manufactured into an AM part with two different AM energy source parameters (EC/DP values). It is readily observable from FIG. 5 that the SLA resin of the present disclosure has a much higher reduced modulus as compared to the commercially available SLA resin (at either AM laser build parameter).

### DETAILED DESCRIPTION

Reference will now be made in detail to the accompanying drawings and Examples, which at least assist in illustrating various pertinent embodiments of the present invention.

### Example: SLA Resin Composition Comparison

Utilizing the above-procedure, three formulations having different 3 comparative runs to show what did not cure, what cured but did not produce a good green form, and what produced a good green form. For the runs, the epoxy was UVA cure 1500 (supplied by UCB), the oxetane was trimethylolopropate oxetane (supplied by Perstorp), the polyester was Bolton TM H2004 (supplier Perstorp) and the photo initiator was PF6CPI6992 (Supplied by Aceto Corp).

The above components were mixed, stirred, and directed into a form and photocured. Non-limiting examples of photo cure include: a UV bulb illuminating a stage with conveyor belt or an energy source (e.g. laser) in an additive manufacturing machine (e.g. SLA machine). The photo cure included: directing a sufficient amount of light (e.g. at a particular wavelength or band of wavelengths) for a sufficient time to cure the SLA formulation/composition into the SLA preform (e.g. SLA green form).

After photocuring, the SLA green form was postcured in a chamber for a sufficient time to provide the final SLA product.

Three formulations were evaluated, and based on 100 g sample, the values of the constituents in each formulation are provided in the below table, in wt. %:

| | | | | Photo | |
|---|---|---|---|---|---|
| SLA | | | | initiator | |
| Formulation | Epoxy | Oxetane | Polyester | (solution) | |
| # | (±2) | (±1) | (±1) | (±0.5) | Notes |
| 1 | 75.09 | 15 | 9.01 | 0.90 | Did not cure |
| 2 | 74.40 | 14.9 | 8.9 | 1.8 | Cured, did |
| | | | | | not provide |
| | | | | | sufficient |
| | | | | | AM build |
| 3 | 68.8 | 13.7 | 8.3 | 9.2 | Cured, |
| | | | | | produced |
| | | | | | AM part |

Without being bound by a particular mechanism or theory, it is believed that an SLA composition having an epoxy, an oxetane, and a hyperbranched polymer in combination with greater than 0.9 wt. % photo initiator can be utilized in an AM process to form a suitable AM part (capable of curing in the AM build via the energy source/laser to form a suitable AM green form and also capable of post curing to provide appropriate strength to the AM part). After this experiment, it was determined that the 1.8 wt. % photo initiator run may not have cured due to some processing parameters and AM machine components/configurations that were remedied.

### Example: Thermogravimetric Analysis of SLA Resin

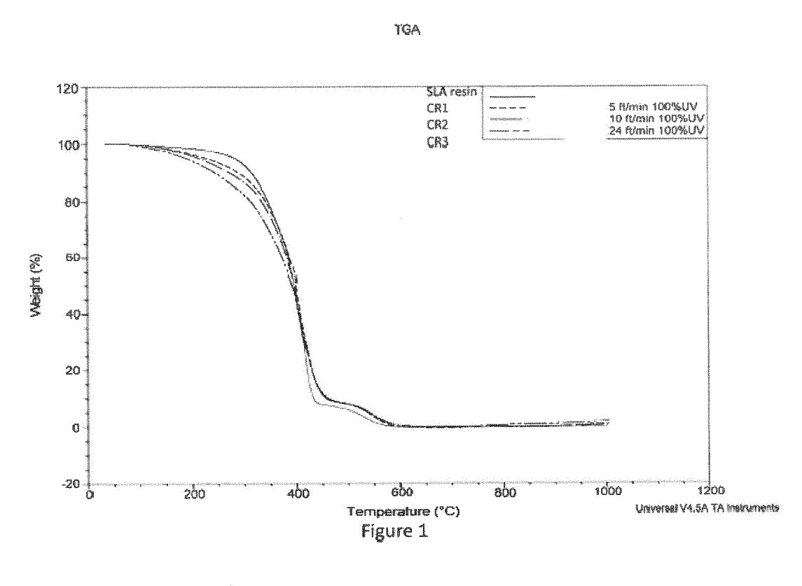

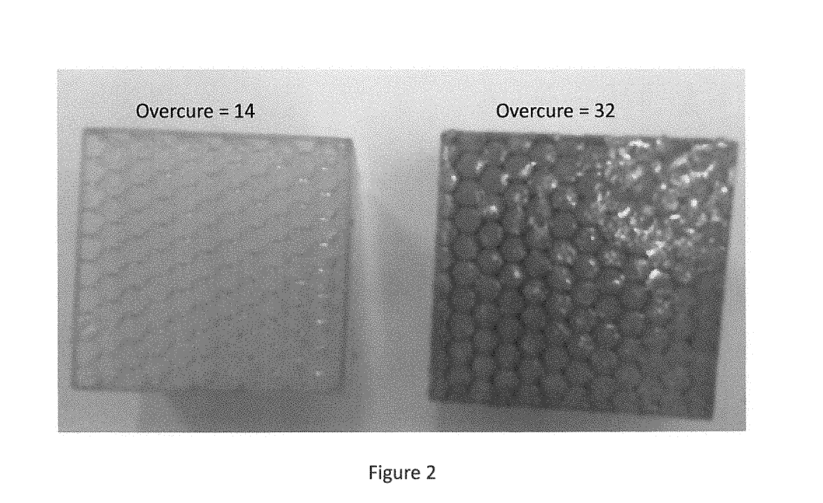

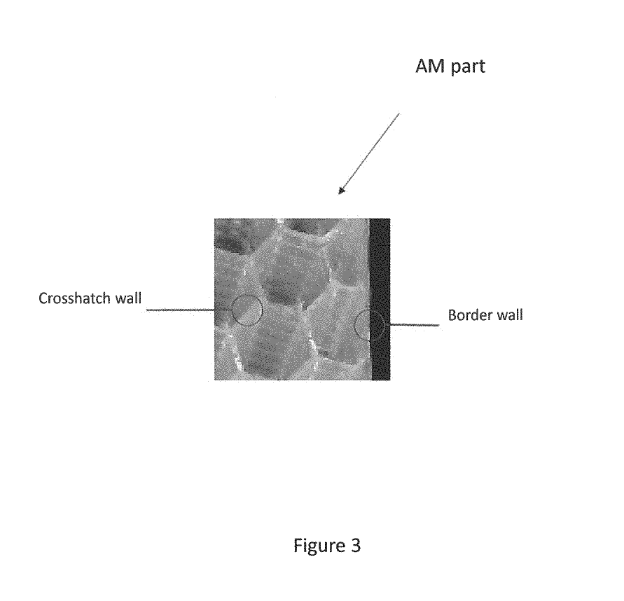

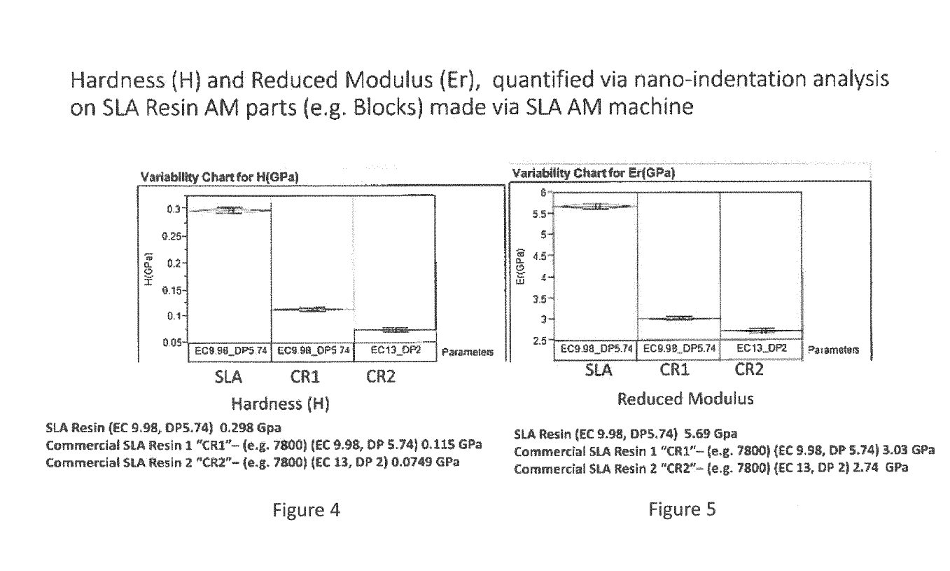

FIG. 1 is a graph depicting the experimental results of completing a thermogravitnetric analysis of the SLA resin in accordance with one or more embodiments of the present disclosure, illustrating the comparative response of the SLA resin to a commercially available SLA resin.

The resins were each cured under three different conditions using a Fusion UV System with a UVA bulb and a 480 V Light Hammer power system (CR1: SL7800 cured at 5 ft/min@100% UV; CR2: SL7800 cured at 10 ft/min@100% UV, and CR1: SL7800 cured at 24 ft/min@100% UV). Thermal gravimetric analysis (TGA) was used to determine the thermal properties of the resulting cured resins, with the included graph depicting the response of the different runs as weight percent vs. temperature. It was observable that the SLA resin had a comparable TGA response in terms of weight loss profile to the commercially available resin at three different cure preparations. Additional differential scanning calorimetry testing showed. that the glass transition temperature of the resin is above 50 degrees C.

### Example: Analytical Assessment of Remains after Burnout

The table below illustrates the measurement data obtained for the ash residue and trace of the SLA resin sample after burnout.

| Elements | Results |
|---|---|
| Pb | <10 ppm |
| Bi | <0.5 ppm |
| Ag | <10 ppm |
| Sb | 15 ppm |
| Zn | 20 ppm |
| Sn | <5 ppm |
| Fe | <0.01% |

It was also observed that the SLA resin (approximately 100 g sample size) provided a very low ash content upon burn-off (<0.005%).

### Example: Analytical Assessment of Viscosity

In order to understand any differences in application in an end use application (e.g. additive manufacturing), viscosity measurements were obtained on an embodiment of the SLA resin as described herein, compared to a commercially available SLA resin.

The viscosity measurements were obtained using a Brookfield Viscometer DVT DVII (Spindle #7). The SLA resin in accordance with the present disclosure was observed to remain stable/have no measurable impact to viscosity after several months on the shelf.

Moreover, the SLA. resins of the present disclosure have a lower viscosity than the commercially available SL7800 SLA resin. It is noted that the SLA resin has comparable results ranging from 140-180 CPS while the SL7800 resin was different in both color and viscosity and appeared to have more turbidity during evaluation, with the viscosity ranging from 180-220 CPS.

### Example: Additive Manufacturing Description

During an additive manufacturing process, the energy source (e.g. laser) polymerizes the SLA resin in successive layers in an AM build to form an AM green form or AM preform. When a layer is completed, a leveling blade (configured as part of the AM machine) is moved across the surface (which includes the most recent build layer and uncured SLA resin (in locations that are not part of the designated build) in order to smooth the surface it before the next layer of AM feedstock material (e.g. SLA resin) is deposited. After the blade smooths the surface, the platform is lowered by a distance equal to the layer thickness of a build layer. Then the energy source again tracks the build pattern and cures the SLA resin in designated areas, adding another build layer onto the AM build. This process of tracing (with energy source) and smoothing (with leveling blade) is repeated until the AM build is complete, forming the AM preform or AM green form part. After the AM build is completed, then the AM preform undergoes a post-cure step to finish the green state parts into an AM part (e.g. configured with sufficient hardness and/or other properties for end-use applications).

In order to additively build a part, the energy source (e.g. UV laser) traces out successive cross-sections of a three-dimensional object in a vat of liquid photosensitive polymer (e.g. including border/edges and interior walls). The resin crosslinks to form a thermoset polymer, while the excess resin remains liquid resin adjacent to the AM build. Once the AM build is completed, the AM build is elevated (e.g. raised out of the vat) and drained to remove excess SLA resin. Once the draining is completed, the final cure is completed by placing the part (or parts) into a UV oven or conveyor, and subjecting the AM parts to a sufficient amount of light for a sufficient amount of time to cure the thermoset polymer.

### Prophetic Example: AM Through Investment Casting-Utilizing SLA Resin

An SLA resin composition is prepared according to the above procedure. Optionally, the SLA resin is degassed (e.g. vacuum/negative pressure pulled across a container housing the resin to evacuate gases from the resin and/or vapor space of the container). The SLA resin is configured into an additive machine configured to utilize SLA resin as the AM build material. An AM green form (preform) is configured from SLA resin, by successively depositing SLA resin, layer by layer, onto a build substrate (e.g. via a sweeper arm) and then curing in place the resin into a predetermined build shape with an energy source (e.g. laser beam configured at an appropriate wavelength to cure the SLA resin).

After the AM build is complete, an AM green form is provided, where the AM green form is configured with a green strength sufficient to be handled and/or further processed to form an AM part.

The excess SLA resin (liquid AM feedstock, not part of the AM green form) is removed from the surface and interstices/lattice structure of the AM green form (e.g. configured with vents and drains). For example, the AM green form can be rinsed with a solvent, liquid, and/or diluent to remove excess SLA resin from the AM green form. As another example, the AM green form is wiped (e.g. with alcohol or other diluent, organic solvent, and/or solvent) to remove excess SLA resin from the AM green form. As still another example, the SLA resin is placed in a spinner and centrifugally spun to remove the excess SLA resin from the surfaces and/or interstices of the AM green form. In some embodiments, one or more combinations of rinsing, wiping, and/or spinning can be combined to remove excess SLA resin from the AM green form.

After the excess SLA resin is removed from the AM green form, the AM green form is configured into an AM part via a post cure step. In some embodiments, the post cure step provides/exposes the entire AM green form to a cure process in order to thoroughly cure the entire AM green form and provide an AM part, where the AM part has a strength higher than the strength (green form strength) of the AM green form. In instances where the SLA resin includes a photo initiator, the post cure step includes exposing the AM green form to a sufficient wavelength for a sufficient time (e.g. optionally at an elevated temperature) to cure and form an AM part.

In order to post cure the AM parts referenced in the examples section, the post cure step is configured with a UVA bulb cure, for a sufficient time (e.g. AM green forms configured on a conveyor belt that passed under a UVA bulb to cure, for 1-2 passes at a rate of 5 ft./min, where the cure zone was configured with a length of approximately 12-18″).

In other embodiments, a closed post cure chamber (e.g. UV oven) is configured to cure the AM green form while the AM green form is exposed to UVA wavelength fight for a sufficient duration and at a sufficient wavelength to form an AM part. In some embodiments, the AM part in the chamber is configured to rotate on a stage within the chamber and/or may contain a heating element.

In some embodiments, a surface finishing step (either automated or by hand) is completed on the AM part in order to configure the surface roughness of the AM part for the end use application (e.g. investment casting).

Next, a plurality of AM parts formed from the above step having specified dimensions and characteristics are configured and attached to form an AM part assembly. In order to attach the AM parts to one another, the SLA resin can be utilized (and cured via UV wand). Alternatively, the AM parts can be glued together with an epoxy glue, utilizing a UV wand. The assembly is sealed (e.g. to close the vents and drains in the individual AM parts) and placed into successive layers of ceramic slurry (and dried between layers) to coat the sealed assembly configured from AM performs made from the SLA resin, such that a ceramic shell is formed over the sealed assembly of AM parts. Optionally, configure the ceramic shell with ports and/or features to enable material addition into the ceramic shell.

Next, the AM assembly is burned out from the ceramic shell by exposing the ceramic shell and AM assembly to a temperature sufficient to burn out the SLA resin but not so high as to sinter the ceramic shell. The resulting ceramic shell (empty) is sintered at an appropriate temperature to sinter the ceramic material, and the sintered ceramic shell is filled with molten metal to form a casted part with an identical configuration as the original AM part assembly. The ceramic shell is removed to provide the metal cast part.

### Example: Proxy for Cure on SLA Machine

The overcure process for the samples made in accordance with the examples section were provided on a UVA bulb cure assembly that included a UVA bulb and a conveyor belt that conveyed samples (AM green forms) under the UVA light at a rate for a sufficient length of time to cure the AM green forms into an AM part. More specifically, using a Fusion UV system the curing conditions that were used to make the SLA resin samples with the white light source are as follows: sample is passed through the chamber at 5 ft./min at a light intensity of 100% (UVA bulb); with an energy density of roughly 5578 mJ/cm² and an intensity of roughly 3048 mW/'cm². In some instances, the sample temperature was increased up to 38° C. during the coring (overcure) process. In some instances, multiple passes were completed on samples in order to effect cure in a component.

### Evaluation of Proxy Cure vs. SLA Machine Cure

The same material (Renshape SL78000 Resin) was prepared and cured: one cure occurred on an SLA machine, while the other cure occurred on the Fusion UV system outlined above. The cure was confirmed to be complete and comparable on both the SLA machine and the Fusion UV system.

### Evaluation of SLA resin vs. Commercial SLA Resin

In order to evaluate the SLA resin in comparison with a commercially available resin for an investment casting application, four large patterns were additively manufactured. The pattern was selected to include several right angles, changes in dimension, and at least one drainage hole and vent. The SLA resin included an epoxy, a hyperbranched polyester, a reactive diluent (e.g. oxetane), and a photo initiator in weight percentages consistent with the ranges previously described herein. The AM printing parameters were the same for each run, including the cure, recoating, energy source (laser beam) spot size, and other printing parameters. After printing, the post printing parameters, including draining time, solvent wash, and post cure in a UV chamber (e.g. to transform the AM preform into the AM part) were the same.

Next, each AM part was surface prepared for ceramic slurry application (as previously described above). Each AM part was also vacuum/pressure checked to ensure there were no leaks prior to ceramic slurry application. In order to enable inspection, each mold was reinforced and braced with wire mesh, which was configured to create a hinge such that the inside of the molds could be accessed after burnout of the SEA resins for ash evaluation.

Each AM part underwent multiple dips in the ceramic slurry and the assembly was allowed to dry. The resulting resin (retained inside the ceramic shell) was subsequently burned out during a heating step.

Upon accessing the inner chamber of the ceramic shells (where the SLA resin AM part was retained), it was qualitatively observed (e.g. visual inspection) there were no apparent mold related cracks or surface quality issues on the internal shell walls; as compared to the prior art resin, the SLA resin produced a smaller amount of ash that was easily removed and did not leave any raised blemishes on the interior of the ceramic shell. Overall, it was observed that the tested resin performed as well or better than the current (prior art) resin in terms of burnout performance.

While various embodiments of the present invention have been described in detail, it is apparent that modifications and adaptations of those embodiments will occur to those skilled in the art. However, it is to be expressly understood that such modifications and adaptations are within the spirit and scope of the present invention.

What is claimed is:

1. A composition, comprising:
an epoxy component;
a reactive diluent component;
a macro dendritic component; and
a photo initiator component; configured in an amount to catalyze the epoxy, the reactive diluent, and the macro dendritic component into a resin configured for additive manufacturing an AM component via vat polymerization.

2. The composition of claim 1, further comprising a stabilizer component configured to stabilize the composition and prevent polymerization outside of the vat polymerization process.

3. The composition of claim 1, further comprising a pigment component configured to color the composition.

4. The composition of claim 1, wherein the photo initiator comprises a IN curable photo initiator.

5. The composition of claim 1, wherein the macro dendritic component comprises: a hyperbranched polyester component.

6. The composition of claim 1, wherein the photo initiator component comprises an onium salt solution.

7. The composition of claim 1, wherein the reactive diluent component comprises an oxetane component.

8. A composition, consisting essentially of:
an epoxy component;
a reactive diluent component including a oxetane;
a macro dendritic component having a hyperbranched polyester; and
a UV curable photo initiator component; configured in an amount to catalyze the epoxy, the reactive diluent, and the macro dendritic component into an KA resin configured for additively manufacturing an AM green form component via stereolithography.

9. The composition of claim 8, wherein the epoxy component comprises: a 3,4-epoxycyclohexylmethyl 3,4-epoxycyclonexanecarboxylate.

10. A composition, consisting of:
at least 65 wt. % to not greater than 85 wt. % an epoxy component;
at least 10 wt. % to not greater than 20 wt. % of a dendritic macromolecule component; and
at least 0.05 wt. % to not greater than 15 wt. % of a photo initiator component.

11. A composition, consisting of:
at least 50 wt. % to not greater than 85 wt. % of an epoxy component;
at least 5 wt. % to not greater than 20 wt. % of a dendritic macromolecule component comprising a hyperbranched polyester;
not greater than 15. wt. % of a reactive diluent component, wherein at least some reactive diluent component is present; and
at least 0.05 wt. % to not greater than 15 wt. % of a photo initiator component.

12. The composition of claim 11, further comprising: at least 0.5 wt. % to not greater than about 5 wt. % of a stabilizer component.

13. The composition of claim 11, further comprising: not greater than about 5 wt. % of a pigment component, wherein at least some pigment component is present.

14. The composition of claim 11, wherein the epoxy component comprises: Uvacure 1500.

15. The composition of claim 11, wherein the photo initiator component comprises an onium salt solution.

16. The composition of claim 11, wherein the reactive diluent component comprises a compound having a four-membered ring.

17. The composition of claim 11, wherein the reactive diluent component comprises oxetane.

18. A method, comprising:
componentcomponent componentcomponentdepositing, positioning, spreading, extruding, spraying, rolling, dipping, wiping, casting, and/or combinations thereof, to form a layer of SLA resin on a surface (e.g. substrate or previous AM build surface).
componentcomponent componentcomponent,
the plurality of AM green form parts including at least a first AM green form part and a second AM green form part;

24. The method of claim 23, wherein the vat polymerization process further comprises stereolithography.

25. The method of claim 23, wherein the AM part comprises a polymeric preform for investment casting.

26. The method of claim 23, wherein the AM part comprises a structural component.

27. The method of claim 23, wherein the AM part comprises a functional component.
